(19) United States
(12) Patent Application Publication
(10) Pub. No.: US 2024/0191072 A1
(43) Pub. Date: Jun. 13, 2024

(54) CURABLE RESIN COMPOSITION, DRY FILM, CURED PRODUCT, AND ELECTRONIC COMPONENT

(71) Applicant: TAIYO HOLDING CO., LTD., Hiki-gun Saitama (JP)

(72) Inventors: Daisuke SHIBATA, Saitama (JP); Chiho UETA, Saitama (JP); Fumitaka KATO, Saitama (JP); Sawako SHIMADA, Saitama (JP); Shotaro TANE, Saitama (JP)

(73) Assignee: TAIYO HOLDING CO., LTD., Hiki-gun, Saitama (JP)

(21) Appl. No.: 18/550,410

(22) PCT Filed: Mar. 11, 2022
(86) PCT No.: PCT/JP2022/011057

§ 371 Date: Sep. 13, 2023

(30) Foreign Application Priority Data
Mar. 15, 2021 (JP) 2021-041776

(51) Int. Cl. C08L 63/04; C08J 7/04; C08K 3/36; C08K 5/00; C09D 7/61; C09D 7/63; C09D 7/65; C09D 163/04

(52) U.S. Cl. CPC C08L 63/04; C08J 7/0427; C08K 3/36; C08K 5/0025; C09D 7/61; C09D 7/63; C09D 7/65; C09D 163/04; C08J 2363/04; C08K 2201/011

(57) ABSTRACT

Provided are a curable resin composition, a dry film, a cured product, and an electronic component including the same that have excellent resolution, higher insulation reliability, and excellent embeddability in a circuit. A curable resin composition includes: (A) a carboxyl group-containing resin; (B) a photopolymerization initiator; (C) a thermosetting resin; and (D) silica, wherein a blending amount of (D) the silica is 10 to 60% by mass relative to a total solid content of the curable resin composition, (D) the silica includes (D-1) nanosilica, (D-1) the nanosilica has an average secondary particle size of 200 nm or less, and a degree of association of (D-1) the nanosilica is 2.3 or less.

### TECHNICAL FIELD

The present invention relates to a curable resin composition, a dry film, a cured product, and an electronic component containing the same.

### BACKGROUND ART

In recent years, as miniaturization and higher performance of electronic components are demanded, semiconductor chips mounted on electronic components are also becoming higher in density and higher in functionality. Along with this, a printed wiring board on which a semiconductor chip is mounted is also required to be miniaturized and densified, and in order to produce a printed wiring board having high integration, insulating materials (for example, solder resists, insulating films, and the like) having high resolution and reliability have been developed.

For example, Patent Literature 1 discloses that a photosensitive resin composition containing a resin having an ethylenically unsaturated group and a carboxyl group, a photopolymerizable monomer having an ethylenically unsaturated group, an epoxy resin, and silica having an average particle size of less than 50 nm can form a fine opening pattern without impairing developability, and can provide an alkali-developable photosensitive film having excellent HAST resistance between fine wirings and high heat resistance. Patent Literature 1 discloses that evaluation was performed using the above photosensitive resin composition for a comb-shaped electrode having a line/space on a circuit of 50 μm/50 μm as HAST resistance evaluation showing insulation reliability.

### CITATION LIST

### Patent Literature

Patent Literature 1: JP 2012-242592 A

### SUMMARY OF INVENTION

### Technical Problem

However, although the photosensitive resin composition disclosed in Patent Literature 1 has the above-described excellent characteristics, it is difficult to embed the photosensitive resin composition between narrow wirings (embeddability in a circuit is low), which may cause insulation failure of a printed wiring board. In addition, higher insulation reliability has been required with the recent increase in density of printed wiring boards, and thus the HAST resistance evaluation using a comb-shaped electrode having a line/space of 50 μm/50 μm on a circuit disclosed in Patent Literature 1 may be insufficient, and excellent HAST resistance under a condition of narrower line/space is required.

Thus, an object of the present invention is to provide a curable resin composition and a dry film having excellent resolution and higher insulation reliability and being excellent in embeddability in a circuit, a cured product thereof, and an electronic component using the same.

### Solution to Problem

As a result of intensive investigations for achieving the above object, the inventors of the present invention have found that a curable resin composition containing silica having a specific degree of association and average secondary particle size can solve the above problems, and have completed the present invention. That is, the present invention is as follows.

The present invention (1) is
a curable resin composition comprising:
(A) a carboxyl group-containing resin;
(B) a photopolymerization initiator;
(C) a thermosetting resin; and
(D) silica, wherein
a blending amount of (D) the silica is 10 to 60% by mass relative to a total solid content of the curable resin composition,
(D) the silica includes (D-1) nanosilica,
(D-1) the nanosilica has an average secondary particle size of 200 nm or less, and
a degree of association of (D-1) the nanosilica is 2.3 or less.

The present invention (2) is
the curable resin composition according to the invention (1), wherein (D) the silica further includes (D-2) another silica different from (D-1) the nanosilica and having an average secondary particle size of more than 200 nm.

The present invention (3) is
the curable resin composition according to the invention (2), wherein (D-2) the other silica has an average secondary particle size of 400 nm to 1600 nm.

The present invention (4) is
the curable resin composition according to any one of the inventions (1) to (3), wherein a blending amount of (D-1) the nanosilica is 50% by mass or more relative to a total blending amount of (D) the silica.

The present invention (5) is
the curable resin composition according to any one of the inventions (1) to (4), wherein the curable resin composition further includes (E) rubber particles.

The present invention (6) is
a dry film comprising a resin layer obtained by applying and drying the curable resin composition according to any one of the inventions (1) to (5) on a film.

The present invention (7) is
a cured product obtained by curing the curable resin composition according to any one of the inventions (1) to (5) or a resin layer of the dry film according to the invention (5).

The present invention (8) is
an electronic component comprising the cured product according to the invention (7).

### Advantageous Effects of Invention

The present invention can provide a curable resin composition and a dry film having excellent resolution and higher insulation reliability and being excellent in embeddability in a circuit, a cured product thereof, and an electronic component using the same.

### DESCRIPTION OF EMBODIMENTS

Hereinafter, the curable resin composition of the present invention will be described, but the present invention is not limited thereto at all.

If isomers are present in the compounds described, all isomers that may be present are usable in the present invention unless otherwise specified.

In the present description, a “resin composition” may be used in the sense of a “curable resin composition”.

In the present description, the term “(meth)acryl” includes both “methacryl” and “acryl”.

In the present description, when the upper limit value and the lower limit value of the numerical range are described separately, all combinations of each lower limit value and each upper limit value are substantially described within a range that does not contradict each other.

### 1. Curable Resin Composition

The curable resin composition of the present invention includes (A) a carboxyl group-containing resin, (B) a photopolymerization initiator, (C) a thermosetting resin, and (D) silica. In addition, the curable resin composition of the present invention can include (E) rubber particles. Further, the curable resin composition of the present invention can include other components.

Hereinafter, each component of the curable resin composition will be described.

### 1-1. (A) Carboxyl Group-Containing Resin

The curable resin composition of the present invention includes a carboxyl group-containing resin, thereby providing excellent adhesion to a base and excellent developability. The carboxyl group-containing resin may be a carboxyl group-containing photosensitive resin having an ethylenically unsaturated group or a carboxyl group-containing resin having no ethylenically unsaturated group. Of these, the carboxyl group-containing resin having an ethylenically unsaturated group is preferable because of being excellent in photocurability and development resistance.

Specific examples of the carboxyl group-containing resin may include the following compounds (may be either an oligomer or a polymer).
(1) A carboxyl group-containing resin obtained by copolymerization of an unsaturated carboxylic acid such as (meth)acrylic acid and an unsaturated group-containing compound such as styrene, α-methylstyrene, lower alkyl(meth)acrylate, or isobutylene.
(2) A carboxyl group-containing urethane resin obtained by polyaddition reaction of diisocyanates such as aliphatic diisocyanates, branched aliphatic diisocyanates, alicyclic diisocyanates, and aromatic diisocyanates; carboxyl group-containing dialcohol compounds such as dimethylolpropionic acid and dimethylolbutanoic acid; and polycarbonate polyols, polyether polyols, polyester polyols, polyolefin polyols, acrylic polyols, bisphenol A alkylene oxide adduct diols, or diol compounds such as compounds having phenolic hydroxyl groups and compounds having alcoholic hydroxyl groups.
(3) A terminal carboxyl group-containing urethane resin obtained by reacting an acid anhydride with a terminal of a urethane resin by polyaddition reaction of diisocyanate compounds such as aliphatic diisocyanates, branched aliphatic diisocyanates, alicyclic diisocyanates, and aromatic diisocyanates; polycarbonate polyols, polyether polyols, polyester polyols, polyolefin polyols, acrylic polyols, bisphenol A alkylene oxide adduct diols, or diol compounds such as compounds having phenolic hydroxyl groups and compounds having alcoholic hydroxyl groups.
(4) A carboxyl group-containing urethane resin obtained by polyaddition reaction of diisocyanates; (meth)acrylate or modified products of partial acid anhydrides thereof of bifunctional epoxy resins such as bisphenol A epoxy resin, hydrogenated bisphenol A epoxy resin, bisphenol F epoxy resin, bisphenol S epoxy resin, bixylenol epoxy resin, and biphenol epoxy resin; carboxyl group-containing dialcohol compounds; and diol compounds.
(5) A carboxyl group-containing urethane resin terminally (meth)acrylated by adding a compound having one hydroxyl group and one or more (meth)acryloyl groups in a molecule such as hydroxyalkyl(meth)acrylate during synthesis of the resin (2) or (4).
(6) A carboxyl group-containing urethane resin terminally (meth)acrylated by adding a compound having one isocyanate group and one or more (meth)acryloyl groups in a molecule, such as an equimolar reactant of isophorone diisocyanate and pentaerythritol triacrylate, during the synthesis of the resin (2) or (4).
(7) A carboxyl group-containing resin obtained by reacting a polyfunctional epoxy resin with (meth)acrylic acid to add a dibasic acid anhydride such as phthalic anhydride, tetrahydrophthalic anhydride, or hexahydrophthalic anhydride to a hydroxyl group present in a side chain.
(8) A carboxyl group-containing resin obtained by reacting (meth)acrylic acid with a polyfunctional epoxy resin obtained by epoxidizing a hydroxyl group of a bifunctional epoxy resin with epichlorohydrin, and adding a dibasic acid anhydride to the hydroxyl group generated.
(9) A carboxyl group-containing polyester resin obtained by reacting a dicarboxylic acid with a polyfunctional oxetane resin and adding a dibasic acid anhydride to a primary hydroxyl group generated.
(10) A carboxyl group-containing resin obtained by reacting an unsaturated group-containing monocarboxylic acid with a reaction product obtained by reacting a compound having a plurality of phenolic hydroxyl groups in one molecule with an alkylene oxide such as ethylene oxide or propylene oxide, and reacting the obtained reaction product with a polybasic acid anhydride.
(11) A carboxyl group-containing resin obtained by reacting an unsaturated group-containing monocarboxylic acid with a reaction product obtained by reacting a compound having a plurality of phenolic hydroxyl groups in one molecule with a cyclic carbonate compound such as ethylene carbonate or propylene carbonate, and reacting the obtained reaction product with a polybasic acid anhydride.
(12) A carboxyl group-containing resin obtained by reacting an epoxy compound having a plurality of epoxy groups in one molecule with a compound having at least one alcoholic hydroxyl group and one phenolic hydroxyl group in one molecule such as p-hydroxyphenethyl alcohol, and an unsaturated group-containing monocarboxylic acid such as (meth)acrylic acid, and reacting the alcoholic hydroxyl group of the obtained reaction product with a polybasic acid anhydride such as maleic anhydride, tetrahydrophthalic anhydride, trimellitic anhydride, pyromellitic anhydride, or adipic anhydride.
(13) A carboxyl group-containing resin obtained by further adding a compound having one epoxy group and one or more (meth)acryloyl groups in the molecule, such as glycidyl(meth)acrylate and α-methylglycidyl(meth)acrylate, to the carboxyl group-containing resin described in (1) to (12).

These carboxyl group-containing resins can be used singly or in combination of two or more.

It is preferable to contain at least one of the carboxyl group-containing resins of (7), (8), (10), (11), and (13) among the carboxyl group-containing resins, and it is more preferable to contain the carboxyl group-containing resin of (7) and (10) from the viewpoint of further improving the insulation reliability.

The acid value of the carboxyl group-containing resin is not particularly limited, and is, for example, 40 to 200 mgKOH/g, preferably 45 to 120 mgKOH/g. When the acid value of the carboxyl group-containing resin is in such a range, alkali development after exposure is facilitated, and resolution is improved.

### 1-2. (B) Photopolymerization Initiator

The photopolymerization initiator according to the present invention is not particularly limited, and a known photopolymerization initiator can be used as the photopolymerization initiator or the photoradical generator.

Examples of the photopolymerization initiator include: bisacylphosphine oxides such as bis-(2,6-dichlorobenzoyl)phenylphosphine oxide, bis-(2,6-dichlorobenzoyl)-2,5-dimethylphenylphosphine oxide, bis-(2,6-dichlorobenzoyl)-4-propylphenylphosphine oxide, bis-(2,6-dichlorobenzoyl)-1-naphthylphosphine oxide, bis-(2,6-dimethoxybenzoyl)phenylphosphine oxide, bis-(2,6-dimethoxybenzoyl)-2,4,4-trimethylpentylphosphine oxide, bis-(2,6-dimethoxybenzoyl)-2,5-dimethylphenylphosphine oxide, and bis-(2,4,6-trimethylbenzoyl)-phenylphosphine oxide;
monoacylphosphine oxides such as 2,6-dimethoxybenzoyldiphenylphosphine oxide, 2,6-dichlorobenzoyldiphenylphosphine oxide, 2,4,6-trimethylbenzoylphenylphosphinic acid methyl ester, 2-methylbenzoyldiphenylphosphine oxide, pivaloylphenylphosphinic acid isopropyl ester, and 2,4,6-trimethylbenzoyldiphenylphosphine oxide;
hydroxyacetophenones such as 1-hydroxy-cyclohexylphenyl ketone, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methyl-propan-1-one, and 2-hydroxy-2-methyl-1-phenyl propan-1-one;
benzoins and benzoin alkyl ethers such as benzoin, benzyl, benzoin methyl ether, benzoin ethyl ether, benzoin n-propyl ether, benzoin isopropyl ether, and benzoin n-butyl ether;
benzophenones such as benzophenone, p-methylbenzophenone, Michler's ketone, methylbenzophenone, 4,4′-dichlorobenzophenone, and 4,4′-bisdiethylaminobenzophenone;
acetophenones such as acetophenone, 2,2-dimethoxy-2-phenylacetophenone, 2,2-diethoxy-2-phenylacetophenone, 1,1-dichloroacetophenone, 1-hydroxycyclohexylphenyl ketone, 2-methyl-1-[4-(methylthio)phenyl]-2-morpholino-1-propanone, 2-benzyl-2-dimethylamino-1-(4-morpholinophenyl)-butanone-1, 2-(dimethylamino)-2-[(4-methylphenyl)methyl]-1-[4-(4-morpholinyl)phenyl]-1-butanone, and N,N-dimethylaminoacetophenone;
thioxanthones such as thioxanthone, 2-ethylthioxanthone, 2-isopropylthioxanthone, 2,4-dimethylthioxanthone, 2,4-diethylthioxanthone, 2-chlorothioxanthone, and 2,4-diisopropylthioxanthone;
anthraquinones such as anthraquinone, chloroanthraquinone, 2-methylanthraquinone, 2-ethylanthraquinone, 2-tert-butylanthraquinone, 1-chloroanthraquinone, 2-amylanthraquinone, and 2-aminoanthraquinone;
ketals such as acetophenone dimethyl ketal and benzyl dimethyl ketal;
benzoic acid esters such as ethyl-4-dimethylaminobenzoate, 2-(dimethylamino)ethyl benzoate, and p-dimethylbenzoic acid ethyl ester;
oxime esters such as 1,2-octanedione, 1-[4-(phenylthio)-,2-(O-benzoyloxime)], ethanone, and 1-[9-ethyl-6-(2-methylbenzoyl)-9H-carbazole-3-yl]-,1-(O-acetyloxime);
titanocenes such as bis(η5-2,4-cyclopentadiene-1-yl)-bis(2,6-difluoro)-3-((1H-pyrrole-1-yl)phenyl)titanium, and bis(cyclopentadienyl)-bis[2,6-difluoro-3-(2-(1-pyr-1-yl)ethyl)phenyl]titanium; and
phenyl disulfide 2-nitrofluorene, butyroin, anisoin ethyl ether, azobisisobutyronitrile, and tetramethylthiuram disulfide. These can be used singly or in combination of two or more.

The blending amount of the photopolymerization initiator is not particularly limited, but for example, it is preferably 0.5 to 20 parts by mass in terms of solid content relative to 100 parts by mass of the carboxyl group-containing resin. When the blending amount of the photopolymerization initiator is in such a range, a curable resin composition having excellent surface curability, less halation, and good resolution can be obtained.

### 1-3. (C) Thermosetting Resin

(C) The thermosetting resin according to the present invention is not particularly limited, and for example, an isocyanate compound, a blocked isocyanate compound, an amino resin, a maleimide compound, a benzoxazine resin, a carbodiimide resin, a cyclocarbonate compound, an epoxy resin, an oxetane compound, an episulfide resin, and the like can be used. These can be used singly or in combination of two or more. Of these, an epoxy resin is preferably used.

Examples of the epoxy resins include: bisphenol A epoxy resins; brominated epoxy resins; novolac epoxy resins; bisphenol F epoxy resins; hydrogenated bisphenol A epoxy resins; biphenyl epoxy resins; glycidylamine epoxy resins; hydantoin epoxy resins; alicyclic epoxy resins; triphenylmethane epoxy resins; trihydroxyphenylmethane epoxy resins; bixylenol or biphenol epoxy resins, or mixtures thereof; bisphenol S epoxy resins; bisphenol A novolac epoxy resins; tetraphenylolethane epoxy resins; heterocyclic epoxy resins; diglycidyl phthalate resins; tetraglycidyl xylenoyl ethane resins; epoxy resins containing naphthalene groups; epoxy resins having a dicyclopentadiene skeleton; epoxy resins having a silsesquioxane skeleton; glycidyl (meth)acrylate copolymer epoxy resins; copolymer epoxy resins of cyclohexylmaleimide and glycidyl (meth)acrylate; epoxy-modified polybutadiene rubber derivative; and CTBN modified epoxy resins. These can be used singly or in combination of two or more.

Of these, an epoxy resin having a dicyclopentadiene skeleton has an alicyclic skeleton, and thus is preferable from the viewpoint of improving the resolution of the curable resin composition of the present invention. In addition, the biphenyl epoxy resin and the novolac epoxy resin have an aromatic ring skeleton, and thus are preferable from the viewpoint of improving the heat resistance of the curable resin composition and the cured product of the dry film of the present invention.

The blending amount of the epoxy resin is not particularly limited, but for example, the epoxy group of the epoxy resin to be blended is preferably 0.8 to 2.5 mol, more preferably 1.0 to 2.0 mol, per 1.0 mol of the carboxyl group contained in (A) the carboxyl group-containing resin. Setting the content to 0.8 mol or more can prevent the carboxyl group from remaining in the cured film, and provide good heat resistance, alkali resistance, electrical insulation, and the like. In addition, setting the blending amount to 2.5 mol or less can prevent the low-molecular-weight epoxy resin from remaining in the dry coating film, and satisfactorily secure the strength and the like of the cured coating film.

### 1-4. (D) Silica

(D) The silica according to the present invention is not particularly limited, and examples thereof include spherical silica, finely powdered silicon oxide, amorphous silica, crystalline silica, and fused silica. These can be used singly or in combination of two or more. As the silica, those disclosed in WO 2020/179559, those prepared by the production method disclosed in JP 2018-168031 A, and the like can be preferably used.

(D) The silica comprises (D-1) nanosilica. In the present description, the nanosilica indicates silica having an average secondary particle size of 200 nm or less. (D-1) The nanosilica has a degree of association of 2.3 or less. Using such silica can provide the effect of the present invention. Although the mechanism by which such an effect can be obtained is not clear, it is presumed that the fluidity of the curable resin composition is improved, thus providing excellent embeddability in a circuit, high insulation reliability because compatibility between silica and a resin component in the curable resin composition is excellent, and excellent resolution because light scattering during exposure can be suppressed.

The degree of association of silica is calculated according to (formula 1).

Degree of association of silica=average secondary particle size of silica/average primary particle size of silica (Formula 1)

The average primary particle size means an average particle size of individual silica particles that are not aggregated. The average primary particle size of silica is determined by measuring the BET specific surface area of silica (an aggregate of particles) and calculating according to the following formula (2) with a true specific gravity of silica being 2.2.

Average primary particle size=6/(true specific gravity×BET specific surface area measurement value) (Formula 2)

The BET specific surface area of silica can be measured by a carrier gas method using nitrogen gas according to JIS Z 8830: 2013. As an evaluation apparatus, AUTOSORB-1 (trade name) manufactured by Quantachrome Instruments is used, and the BET specific surface area is measured by analyzing the obtained adsorption isotherm using a multipoint method.

The moisture adsorbed on the sample surface and in the structure is considered to affect the nitrogen adsorption ability, and thus when the BET specific surface area is measured, pretreatment of moisture removal by heating is first performed. Specifically, as pretreatment, the silica for measurement is predried on a hot plate and then heat-treated at 800° C. for 1 hour to prepare a sample for measurement. After this pretreatment is performed, the BET specific surface area is measured at an evaluation temperature of 77 K.

The average secondary particle size means an average particle size of aggregates of primary particles. In addition, the average secondary particle size in the present description is a volume average particle size (D50 based on vol %) obtained by measuring aggregates of silica by a dynamic light scattering method using a laser diffractometer. That is, when the silica aggregate contains primary particles, the average secondary particle size is a measured value including the particle size of the primary particles.

Specifically, the average secondary particle size of silica is measured by the following method.
Particle size distribution meter: Microtrac MT3300EX manufactured by Nikkiso Co., Ltd.
Circulating device: ASVR manufactured by Nikkiso Co., Ltd.

First, measurement conditions are input according to the following procedure. The software attached to Microtrac (“particle size distribution measurement”) is started, and in the SETUP screen, the time is set from the measurement condition setting option. The Setzero time is set to 30 sec, the measurement to 30 sec, and the number of measurements to 2. Then, analysis conditions are input. In the analysis information, the particle refractive index is set to 1.81 (fixed value: average value of refractive indexes of all inorganic substances), the transmittance is set to transmittance in the characteristics of the particle, and the shape is set to non-spherical. In addition, in the solvent information, PMA (propylene glycol monomethyl ether acetate) is selected, and the solvent refractive index is set to 1.4. Then, a scale setting is input. In the particle size range, the minimum particle size is set to 0.021 μm and the maximum particle size is set to 704 μm. Then, a sampling system is input. The number of times of cleaning in ASVR is set to 4, the flow rate is set to 50%, the ultrasonic output is set to 40 W, and the ultrasonic time is set to 300 sec. When all the measurement conditions have been entered, in the setting of the measurement conditions, Save is pressed to close.

Subsequently, the sample is adjusted by the following procedure. As the sample, raw material silica before being blended in the curable resin composition is used. When silica powder is blended, the powder is used as a sample, and when silica is dispersed in a solvent or the like and blended, the solvent dispersion is used as a sample. A sample with 0.3 g is weighed in a screw bottle, 30 g of propylene glycol monomethyl ether acetate is added little by little using a dropper, and the sample is dispersed by shaking the screw bottle to prepare an adjusted sample. The adjusted sample is not subjected to external dispersion or preliminary dispersion. Then, the adjusted sample is measured. A click on the particle size distribution measurement in the software attached to the Microtrac is performed to open the sample loading screen. Several drops of the adjusted sample are put in the sample inlet of the main body using a dropper. When a red instruction bar is displayed on the sample loading screen, the adjusted sample is dropped to the sample inlet until the instruction bar indicates green from red. When the instruction bar indicates green, the measurement button is pressed to start the measurement. Adjustment of the sample to measurement of the adjusted sample is performed within 5 minutes. The value of the cumulative volume average size of 50% displayed as the measurement result is taken as the value of the average particle size D50.

Herein, the upper limit value of the average primary particle size of (D-1) the nanosilica is 200 nm or less, preferably 150 nm or less, more preferably 100 nm or less, and still more preferably 90 nm or less. In addition, the lower limit value of the average primary particle size of (D-1) the nanosilica is 5 nm or more, preferably 10 nm or more, and more preferably 12 nm or more.

The upper limit value of the average secondary particle size of (D-1) the nanosilica is 200 nm or less, preferably 180 nm or less, and more preferably 160 nm or less. The lower limit value of the average secondary particle size of (D-1) the nanosilica is 10 nm or more, preferably 15 nm or more, and more preferably 19 nm or more.

The degree of association of (D-1) the nanosilica is 2.3 or less, preferably 2.0 or less. In addition, the degree of association of (D-1) the nanosilica is preferably 1.2 or more, and more preferably 1.4 or more. When the degree of association is 1.2 or more, the fluidity of the curable resin composition is improved, and the embeddability in a circuit is more excellent.

The degree of association of silica can be adjusted, for example, by controlling the concentration of the alkali catalyst, the temperature of the reaction liquid, and the like within a range of a predetermined addition rate at which the liquid (B) is added to the liquid (A) in the production method disclosed in JP 2018-168031 A described above (refer to paragraph 0049 of JP 2018-168031 A).

In the present invention, the average primary particle size, the average secondary particle size, and the degree of association represent values in a solvent dispersion or powder that is in a state before being blended in the curable resin composition, as is clear from the above measurement method.

(D) The silica can further include silica different from (D-1) the nanosilica (hereinafter referred to as (D-2) other silica). (D-2) The other silica refers to silica having an average secondary particle size of more than 200 nm. (D-2) The average secondary particle size of the other silica is preferably 400 to 1600 nm. When (D-2) the other silica is blended into the curable resin composition, the curable resin composition is excellent in coatability as compared with (D-1) the nanosilica. Further, using (D-1) the nanosilica in combination with (D-2) the other silica can maintain characteristics such as resolution and crack resistance while reducing the blending amount of (D-1) the nanosilica. Therefore, including (D-2) the other silica can provide the curable resin composition of the present invention having excellent coatability.

The blending amount of (D) the silica is 10 to 60% by mass, more preferably 10 to 50% by mass, still more preferably 10 to 35% by mass, even more preferably 15 to 35% by mass, particularly preferably 15 to 30% by mass, and most preferably 20 to 30% by mass relative to the total solid content of the curable resin composition of the present invention. When the blending amount of (D) the silica is in such a range, it is possible to obtain a curable resin composition that is more excellent in resolution and embeddability in a circuit and further more excellent in insulation reliability, crack resistance, and heat resistance of a cured product. The blending amount of (D) the silica is a value obtained by rounding off the first decimal place.

The blending amount of (D-1) the nanosilica can be 100% by mass relative to the total blending amount of (D) the silica. In addition, the blending amount of (D-1) the nanosilica can be set to 50% by mass or more and less than 100% by mass relative to the total blending amount of (D) the silica, and is more preferably 90% by mass or more and less than 100% by mass. When the blending amount of (D-1) the nanosilica is 100% by mass, a curable resin composition having more excellent resolution can be obtained. Meanwhile, when the blending amount of (D-1) the nanosilica is 50% by mass or more and less than 100% by mass, the coatability of the curable resin composition of the present invention can be improved while characteristics such as resolution and crack resistance are maintained.

The blending amount of (D-2) the other silica can be set to 50% by mass or less, and more preferably 10% by mass or less relative to the total blending amount of (D) the silica.

### 1-5. (E) Rubber Particles

(E) The rubber particles according to the present invention are not particularly limited, and for example, a silicone-based elastomer, a butadiene-based elastomer, a styrene-based elastomer, an acryl-based elastomer, a polyolefin-based elastomer, a silicone-acryl-based composite elastomer, or the like can be used. These can be used singly or in combination of two or more. Of these, the butadiene-based elastomer and the styrene-based elastomer are preferably used.

The average secondary particle size of (E) the rubber particles is not particularly limited, but is, for example, preferably 2 μm or less, and more preferably 0.01 μm to 1 μm. When the average secondary particle size of the rubber particles is in such a range, a curable resin composition more excellent in crack resistance can be obtained.

The blending amount of (E) the rubber particles is 0 to 32% by mass, preferably 0.1 to 10% by mass, and more preferably 0.5 to 7% by mass relative to the total solid content of the curable resin composition of the present invention. When the blending amount of (E) the rubber particles is in such a range, a curable resin composition further excellent in embeddability in a circuit and crack resistance when cured can be obtained.

### 1-6. Other Components

In the curable resin composition of the present invention, other components commonly known in the field of electronic materials can be added. Examples of the other components include photocurable compounds and thermosetting compounds other than the above compounds; colorants; thermosetting catalysts; organic solvents; thermal polymerization inhibitors; UV absorbers; silane coupling agents; plasticizers; flame retardants; antistatic agents; antiaging agents; antioxidants; antibacterial/antifungal agents; antifoaming agents; leveling agents; thickeners; adhesion agents; thixotropic agents; photoinitiator aids; sensitizers; photobase generators; thermoplastic resins; elastomers; organic fillers; release agents; surface treatment agents; dispersants; dispersing aids; surface modifiers; stabilizers; and phosphors. These can be used singly or in combination of two or more.

### 2. Dry Film

The curable resin composition of the present invention can be applied onto a film (hereinafter, also referred to as a “first film”) and then dried to form a dry film.

The dry film of the present invention can be obtained by diluting the curable resin composition of the present invention with an organic solvent to adjust the viscosity to an appropriate viscosity, applying the composition to the first film to have a uniform thickness with a comma coater, a blade coater, a lip coater, a rod coater, a squeeze coater, a reverse coater, a transfer roll coater, a gravure coater, a spray coater, or the like, and typically drying the composition at a temperature of 50 to 130° C. for 1 to 30 minutes. The coating film thickness is not particularly limited, but in general, the film thickness after drying can be appropriately set in a range of 3 to 100 μm, preferably 5 to 40 μm.

As the first film, a plastic film can be suitably used, and it is preferable to use a plastic film such as a polyester film such as polyethylene terephthalate, a polyimide film, a polyamideimide film, a polypropylene film, or a polystyrene film. The thickness of the first film is not particularly limited, but can be generally in the range of 10 to 150 μm.

The curable resin composition of the present invention is applied onto the first film and dried to obtain a resin layer on the first film, and then a peelable film (hereinafter, also referred to as a “second film”) may be further laminated on the surface of the resin layer for the purpose of, for example, preventing adhesion of dust to the surface of the resin layer. As the peelable second film, for example, a polyethylene film, a polytetrafluoroethylene film, a polypropylene film, surface-treated paper, or the like can be used, and any film may be used as long as the adhesive force between the resin layer and the second film is smaller than the adhesive force between the resin layer and the first film when the second film is peeled off.

The drying treatment performed after applying the curable resin composition of the present invention onto the first film can be performed using a hot air circulating drying furnace, an IR furnace, a hot plate, a convection oven, or the like.

### 3. Cured Product

The cured product of the present invention is obtained by curing the above-described curable resin composition or the resin layer of the dry film.

The method for obtaining a cured product from the curable resin composition or the dry film is not particularly limited, and can be appropriately changed according to the composition of the curable resin composition.

As a method for curing the curable resin composition of the present invention, for example, the curable resin composition of the present invention is applied onto a substrate by a method such as a dip coating method, a flow coating method, a roll coating method, a bar coating method, a screen printing method, or a curtain coating method with the viscosity adjusted to a viscosity suitable for the application method using an organic solvent or the like, and then the organic solvent contained in the composition is volatilized and dried (temporarily dried) at a temperature of 60 to 100° C., allowing to form a tack-free resin layer on the substrate.

Examples of the method for forming a cured product by the dry film of the present invention include a method in which a resin layer of the dry film is bonded onto a substrate by a laminator or the like so that the resin layer comes into contact with the substrate, and then the first film is peeled off to laminate (form) the resin layer on the substrate.

A cured product can be obtained by subjecting the resin layer to an exposure treatment.

Examples of these exposure treatments include a method in which a resin layer is formed on a circuit board, and then the resin layer is selectively exposed to an active energy ray through a photomask on which a predetermined pattern is formed.

More specifically, the cured product of the present invention can be obtained as follows.

The resin layer on the substrate, prepared by the above method, is selectively exposed to an active energy ray through a photomask on which a predetermined pattern is formed, and an unexposed portion is developed with a dilute alkaline aqueous solution (for example, 0.3 to 3% by mass of sodium carbonate aqueous solution) to form a pattern of the resin layer. Further, the cured product of the present invention can be obtained by irradiating the resin layer with an active energy ray and then thermally curing the resin layer (for example, 30 to 120 minutes at 100 to 220° C.), irradiating the resin layer with an active energy ray after thermal curing, or performing final finish curing only by thermal curing.

As an exposure machine used for irradiation with an active energy ray, any device may be used as long as it is equipped with a high pressure mercury lamp, an ultra-high pressure mercury lamp, a metal halide lamp, a mercury short arc lamp, or the like, and emits ultraviolet rays in the range of 350 to 450 nm, and a direct drawing device (for example, a laser direct imaging apparatus that directly draws an image with a laser using CAD data from a computer) can also be used. The lamp light source or the laser light source of the direct drawing machine may have a maximum wavelength in the range of 350 to 450 nm. The exposure amount for image formation varies depending on the film thickness and the like, but can be generally in the range of 10 to 1000 mJ/cm², preferably 20 to 800 mJ/cm².

Examples of the developing method include a dipping method, a shower method, a spray method, and a brush method, and as the developer, an aqueous alkali solution such as potassium hydroxide, sodium hydroxide, sodium carbonate, potassium carbonate, sodium phosphate, sodium silicate, ammonia, and amines can be used.

### 4. Electronic Component

The curable resin composition and the dry film of the present invention are applied and dried or laminated at a predetermined position on a substrate, and cured to form a cured product, thereby forming a circuit board, and an electronic component such as a printed wiring board can be obtained.

The curable resin composition and the dry film of the present invention are suitably used for forming a cured film on a circuit board, more suitably used for forming a permanent coating, and still more suitably used for forming a solder resist, an interlayer insulating layer, and a coverlay. In addition, it is suitable for forming a printed wiring board including a fine wiring pattern requiring high reliability, for example, a package board, particularly, a permanent coating (particularly, solder resist) for FC-BGA. For example, it is also suitable for forming a fine pitch having an L/S of 10 μm/10 μm or less, that is, a fine pitch having a line width L of 10 μm or less and an inter-line space of 10 μm or less. In addition, the curable resin composition and the dry film of the present invention can also be suitably used for a printed wiring board having a wiring pattern, for example, a printed wiring board for high frequency even when the roughness of the circuit surface is small. For example, even when the surface roughness Ra is 0.5 μm or less, particularly 0.3 μm or less, it can be suitably used.

### EXAMPLES

Then, the present invention will be described in detail with reference to Examples and Comparative Examples, but the present invention is not limited thereto at all.

### <<<Preparation of Curable Resin Composition>>>

Hereinafter, a preparation procedure of each curable resin composition (Compositions of Examples 1 to 8 and Comparative Examples 1 to 3) will be described.

### <<Synthesis of Carboxyl Group-Containing Resin>>

### Synthesis Example 1 Synthesis of Carboxyl Group-Containing Resin A1

First, 119.4 parts by mass of a novolac cresol resin (trade name: Shonol CRG 951, manufactured by Aica Kogyo Co., Ltd., OH equivalent: 119.4), 1.19 parts by mass of potassium hydroxide, and 119.4 parts by mass of toluene were introduced into an autoclave equipped with a thermometer, a nitrogen introducing device and an alkylene oxide introducing device, and a stirring device, and the inside of the system was purged with nitrogen while being stirred, and the temperature was raised by heating. Then, 63.8 parts by mass of propylene oxide was gradually added dropwise, and the mixture was reacted at 125 to 132° C. and 0 to 4.8 kg/cm² for 16 hours. Thereafter, the mixture was cooled to room temperature, and 1.56 parts by mass of 89% phosphoric acid was added to and mixed with the reaction solution to neutralize potassium hydroxide, thereby obtaining a propylene oxide reaction solution of a novolac cresol resin having a solid content of 62.1% and a hydroxyl value of 182.2 mg KOH/g (307.9 g/eq). This was obtained by adding 1.08 mol of propylene oxide on average per equivalent of the phenolic hydroxyl group.

With the obtained novolac cresol resin, 293.0 parts by mass of the propylene oxide reaction solution, 43.2 parts by mass of acrylic acid, 11.53 parts by mass of methanesulfonic acid, 0.18 parts by mass of methylhydroquinone, and 252.9 parts by mass of toluene were introduced into a reactor equipped with a stirrer, a thermometer, and an air blowing tube, and air was blown at a rate of 10 ml/min and reaction occurred at 110° C. for 12 hours while stirring. In the water produced by the reaction, 12.6 parts by mass of water was distilled out as an azeotropic mixture with toluene. Thereafter, the reaction solution was cooled to room temperature, neutralized with 35.35 parts by mass of a 15% aqueous sodium hydroxide solution, and then washed with water. Thereafter, toluene was distilled off while being replaced with 118.1 parts by mass of diethylene glycol monoethyl ether acetate, using an evaporator to obtain a novolac acrylate resin solution. Next, 332.5 parts by mass of the obtained novolac-type acrylate resin solution and 1.22 parts by mass of triphenylphosphine were introduced into a reactor equipped with a stirrer, a thermometer, and an air blowing tube, air was blown at a rate of 10 ml/min, 60.8 parts by mass of tetrahydrophthalic anhydride was gradually added while stirring, and the mixture was reacted at 95 to 101° C. for 6 hours, cooled, and then taken out. In this way, a solution of the photosensitive carboxyl group-containing resin A1 having a solid content of 70.6% and a solid acid value of 87.7 mgKOH/g was obtained.

### Synthesis Example 2 Synthesis of Carboxyl Group-Containing Resin A2

To 650 parts by mass of diethylene glycol monoethyl ether acetate, 1070 parts by mass of an orthocresol novolac epoxy resin (EPICLON N-695 manufactured by DIC Corporation, softening point 95° C., epoxy equivalent 214, average number of functional groups 7.6) (the number of glycidyl groups (the total number of aromatic rings): 5.0 mol), 360 parts by mass of acrylic acid (5.0 mol), and 1.5 parts by mass of hydroquinone were added, heated and stirred to 100° C., and uniformly dissolved. Then, 4.3 parts by mass of triphenylphosphine was added, and the mixture was heated to 110° C. and reacted for 2 hours. Thereafter, 1.6 parts by mass of triphenylphosphine was further added, and heated to 120° C. and further reacted for 12 hours. Then, 525 parts by mass of an aromatic hydrocarbon (Solvesso 150) and 608 parts by mass (4.0 mol) of tetrahydrophthalic anhydride were added to the obtained reaction solution, and the reaction was performed at 110° C. for 4 hours. Further, 142.0 parts by mass (1.0 mol) of glycidyl methacrylate was added to the obtained reaction solution, and the reaction was performed at 115° C. for 4 hours to obtain a solution of a carboxyl group-containing resin A2 having a solid content acid value of 77 mgKOH/g and a solid content of 65%.

### <<Preparation of Silica Particle Organic Solvent Dispersion>>

### Preparation Example 1: Preparation of Silica Particle Organic Solvent Dispersion D1

To 500 g of a silica particle aqueous dispersion (Quartron PL-3 manufactured by FUSO CHEMICAL CO., LTD., silica concentration: 20 wt %), 400 g of γ-butyrolactone (GBL) was added, the mixture was stirred, and distilled under reduced pressure with a rotary evaporator, thereby replacing the dispersion medium of the silica sol with γ-butyrolactone. This prepared a silica particle organic solvent dispersion D1 (500 g) having a SiO₂ concentration of 20 wt % and a water concentration of 1 wt % or less. The obtained silica nanoparticles had an average primary particle size of 35 nm, an average secondary particle size of 70 nm, and a degree of association of 2.0.

### Preparation Example 2: Preparation of Silica Particle Organic Solvent Dispersion D2

A liquid prepared by mixing 2945 g of methanol with 377.9 g of pure water and 218 g of 29% by weight of ammonia water was added to a 5-L reaction vessel with a stirrer having a cooling function, and while stirring at 300 rpm, a liquid prepared by dissolving 309 g of tetramethoxysilane (TMOS) in 79 g of methanol was added at 11 mL/min while maintaining the liquid temperature in the reaction vessel at 20° C., and thus a reaction liquid was prepared and a silica sol was obtained. To 500 g of the prepared silica sol, 385 g of γ-butyrolactone (GBL) was added, the mixture was stirred, and distilled under reduced pressure with a rotary evaporator, thereby replacing the dispersion medium of the silica sol with γ-butyrolactone. This prepared a silica particle organic solvent dispersion D2 (500 g) having a SiO₂ concentration of 8 wt % and a water concentration of 1 wt % or less. The obtained silica nanoparticles had an average primary particle size of 83 nm, an average secondary particle size of 113 nm, and a degree of association of 1.4.

### Preparation Example 3: Preparation of Silica Particle Organic Solvent Dispersion D3

A liquid prepared by mixing 2945 g of methanol with 411.36 g of pure water, 108 g of 29% by weight of ammonia water, and 46.5 g of colloidal silica (silica concentration: 4% by weight, average secondary particle size: 8 nm) was added to a 5-L reaction vessel with a stirrer having a cooling function, and while stirring at 300 rpm, a liquid prepared by dissolving 309 g of tetramethoxysilane (TMOS) in 79 g of methanol was added at 0.74 mL/min while maintaining the liquid temperature in the reaction vessel at 20° C., and thus a reaction liquid was prepared and a silica sol was obtained. To 500 g of the prepared silica sol, 385 g of γ-butyrolactone (GBL) was added, the mixture was stirred, and distilled under reduced pressure with a rotary evaporator, thereby replacing the dispersion medium of the silica sol with γ-butyrolactone. This prepared a silica particle organic solvent dispersion D3 (500 g) having a SiO₂ concentration of 8 wt % and a water concentration of 1 wt % or less. The obtained silica nanoparticles had an average primary particle size of 13 nm, an average secondary particle size of 19 nm, and a degree of association of 1.5.

### Preparation Example 4: Preparation of Silica Particle Organic Solvent Dispersion D4

A liquid prepared by mixing 2945 g of methanol with 373.15 g of pure water, 218 g of 29% by weight of ammonia water, and 5.4 g of colloidal silica (silica concentration: 12% by weight, average secondary particle size: 25 nm) was added to a 5-L reaction vessel with a stirrer having a cooling function, and while stirring at 300 rpm, a liquid prepared by dissolving 309 g of tetramethoxysilane (TMOS) in 79 g of methanol was added at 11 mL/min while maintaining the liquid temperature in the reaction vessel at 20° C., and thus a reaction liquid was prepared and a silica sol was obtained. To 500 g of the prepared silica sol, 385 g of γ-butyrolactone (GBL) was added, the mixture was stirred, and distilled under reduced pressure with a rotary evaporator, thereby replacing the dispersion medium of the silica sol with γ-butyrolactone. This prepared a silica particle organic solvent dispersion D4 (500 g) having a SiO₂ concentration of 8 wt % and a water concentration of 1 wt % or less. The obtained silica nanoparticles had an average primary particle size of 84 nm, an average secondary particle size of 153 nm, and a degree of association of 1.8.

### Preparation Example 5: Preparation of Silica Particle Organic Solvent Dispersion D5

To 500 g of a silica particle aqueous dispersion (Quartron PL-1 manufactured by FUSO CHEMICAL CO., LTD., silica concentration: 12 wt %), 440 g of γ-butyrolactone (GBL) was added, the mixture was stirred, and distilled under reduced pressure with a rotary evaporator, thereby replacing the aqueous dispersion medium of the silica sol with γ-butyrolactone. This prepared a silica particle organic solvent dispersion D5 (500 g) having a SiO₂ concentration of 12 wt % and a water concentration of 1 wt % or less. The obtained silica nanoparticles had an average primary particle size of 15 nm, an average secondary particle size of 40 nm, and a degree of association of 2.7.

### Preparation Example 6: Preparation of Silica Particle Organic Solvent Dispersion D6

To 500 g of the silica particle aqueous dispersion (Quartron PL-10H manufactured by FUSO CHEMICAL CO., LTD., silica concentration: 23 wt %), 385 g of γ-butyrolactone (GBL) was added, stirred, and distilled under reduced pressure with a rotary evaporator to prepare a silica particle organic solvent dispersion D6 (500 g) in which the aqueous dispersion medium of the silica sol was replaced with γ-butyrolactone and the SiO₂ concentration was 23% by weight and the concentration of water was 1% by weight or less. The obtained silica nanoparticles had an average primary particle size of 90 nm, an average secondary particle size of 220 nm, and a degree of association of 2.4.

### Preparation Example 7: Preparation of Silica Particle Organic Solvent Dispersion D7

SIRPMA 30 WT %-K22 (PMA dispersion with silica concentration of 30 wt %, average primary particle size of 120 nm, average secondary particle size of 250 nm, degree of association of 2.1) manufactured by CIK Nanotech Co., Ltd. was used as it was.

### <Measurement of Average Primary Particle Size of Silica Particles>

Each silica particle organic solvent dispersion was predried on a hot plate, and then heat-treated at 800° C. for 1 hour to prepare a measurement sample. Using the measurement sample, measurement was performed according to JIS Z 8830: 2013 by a carrier gas method using nitrogen gas. As an evaluation apparatus, AUTOSORB-1 (trade name) manufactured by Quantachrome Instruments was used to measure the BET specific surface area by analyzing the adsorption isotherm using a multipoint method. The value of 2727/BET specific surface area (m²/g) was calculated with the true specific gravity of silica as 2.2 to determine the average primary particle size.

### <Average Secondary Particle Size of Silica Particles>

Using the silica particle organic solvent dispersion prepared in Preparation Examples 1 to 7, a volume-based particle size distribution was measured by a dynamic light scattering method using Microtrac MT3300EX manufactured by Nikkiso Co., Ltd., and an average secondary particle size (D50 based on vol %) was measured.

### <Degree of Association of Silica Particles>

The degree of association of the silica particles was determined from the average primary particle size and the average secondary particle size of the silica particles calculated by the above-described method using the following calculation formula.

Degree of association=(average secondary particle size)/(average primary particle size)

### <<<Preparation of Curable Resin Composition>>>

### <Raw Materials>

### (A) Carboxyl Group-Containing Resin

Carboxyl group-containing resin A1: one synthesized by the method of Synthesis Example 1
Carboxyl group-containing resin A2: one synthesized by the method of Synthesis Example 2

### (B) Photopolymerization Initiator

2,4,6-Trimethylbenzoyl-diphenylphosphine oxide manufactured by IGM Resins

### (C) Epoxy Resin

Dicyclopentadiene epoxy resin HP-7200L, manufactured by DIC Corporation

### (D) Silica

Silica particle organic solvent dispersion D1: one prepared by the method of Preparation Example 1
Silica particle organic solvent dispersion D2: one prepared by the method of Preparation Example 2
Silica particle organic solvent dispersion D3: one prepared by the method of Preparation Example 3
Silica particle organic solvent dispersion D4: one prepared by the method of Preparation Example 4
Silica particle organic solvent dispersion D5: one prepared by the method of Preparation Example 5
Silica particle organic solvent dispersion D6: one prepared by the method of Preparation Example 6
Silica particle organic solvent dispersion D7: one prepared by the method of Preparation Example 7

### (D-2) Other Silicas

Silica D2-1: SFP-20M (average secondary particle size 400 nm), manufactured by Denka Company Limited
Silica D2-2: SO-C4 (average secondary particle size: 1000 mu), manufactured by Admatechs Company Limited
Silica D2-3: SO-C5 (average secondary particle size: 1600 mu), manufactured by Admatechs Company Limited

### (E) Rubber Particles

Rubber particles E1: PARALOIDO EXL-2655 (average secondary particle size: 500 nm), manufactured by the Dow Chemical Company
Rubber particles E2: XER-91 (average secondary particle size: 400 nm), manufactured by JSR Corporation

### Thermosetting Catalyst

Thermosetting catalyst 1: melamine
Thermosetting catalyst 2: dicyandiamide DICY

### Acrylate Monomer

Acrylate monomer: dipentaerythritol hexaacrylate DPHA, manufactured by Nippon Kayaku Co., Ltd.

The blending amounts of the components shown in Tables 1 and 2 all represent parts by mass in terms of solid content.

### <Preparation Method of Curable Resin Composition>

For the curable resin compositions of Examples and Comparative Examples, various components in Tables 1 and 2 were blended in the proportions (parts by mass) shown in the tables, premixed with a stirrer, and then kneaded with a bead mill to prepare curable resin compositions. The blending amount of each component in Tables 1 and 2 is described in terms of solid content mass. In addition, as the stirring conditions of the stirrer, the number of revolutions was 800 rpm, the stirring time was 10 min, the stirrer blade had 12 cm, and as the bead mill, a conical K-8 (manufactured by Buhler) was used, and kneading was performed under the conditions of zirconia beads, the number of revolutions of 1000 rpm, the discharge amount of 20%, the bead particle size of 0.65 mm, and the filling rate of 88%.

### <Production of Dry Film>

Each of the curable resin compositions of Examples and Comparative Examples prepared above was applied onto a 38 μm polyethylene terephthalate film using an applicator, and dried at 80° C. for 10 minutes in a hot air circulating drying furnace to prepare a dry film having a 23 μm thick resin layer.

### <<<Evaluation>>>

The dry films according to Examples and Comparative Examples were evaluated as follows.

### <<Evaluation of Resolution>>

A copper-clad laminate having a copper foil thickness of 35 μm with 1.6 mm thick FR-4 was subjected to copper etching treatment corresponding to 1.0 μm by CZ-8101B treatment manufactured by MEC Corporation. The dry film of each of Examples and Comparative Examples was laminated under the conditions of a vacuum pressure of 3 hPa and a vacuum time of 30 seconds in a first chamber at 90° C. using a vacuum laminator (CVP-300: manufactured by Nikko-Materials Co., Ltd.), and then pressed under the conditions of a press pressure of 0.5 MPa and a press time of 30 seconds.

Then, exposure was performed in each opening pattern with an exposure apparatus equipped with a high-pressure mercury lamp. The exposure amount was adjusted with a step tablet (Photec 41 stages) so that the gloss sensitivity was 10 stages, and then the polyethylene terephthalate film was peeled off from the photosensitive dry film to expose the photosensitive resin layer. Thereafter, development was performed for 60 seconds with a 1% by mass of Na₂CO₃ aqueous solution at 30° C. under the condition of a spray pressure of 2 kg/cm². The substrate having this cured film was irradiated with ultraviolet rays in a UV conveyor furnace under the condition of an integrated exposure amount of 1000 mJ/cm², and then heated and cured at 170° C. for 60 minutes. The opening size of the obtained cured product was observed by a SEM at a magnification of 1500 times, and whether or not halation or undercut occurred was evaluated according to the following criteria. The results are shown in Tables 1 and 2.

### <Evaluation Criteria>

⊚: A good opening size was obtained at an opening size of 35 μm.
◯: A good opening size was obtained at an opening size of 40 μm, but a good opening size was not obtained at an opening size of 35 μm.
Δ: A good opening size was obtained at an opening size of 50 μm, but a good opening size was not obtained at an opening size of 40 μm.
X: A good opening size was not obtained at an opening size of 50 μm.

### <<Evaluation of Embeddability in a Circuit>>

A substrate on which a copper circuit having a copper thickness of 18 μm and L/S=20 μm/20 μm was formed was subjected to an etching treatment corresponding to 1.0 μm by the treatment with CZ-8101B manufactured by MEC Corporation. The dry film of each of Examples and Comparative Examples was laminated under the conditions of a vacuum pressure of 3 hPa and a vacuum time of 30 seconds in a first chamber at 90° C. using a vacuum laminator (CVP-300: manufactured by Nikko-Materials Co., Ltd.), and then pressed under the conditions of a press pressure of 0.5 MPa and a press time of 30 seconds. Then, exposure was performed in each opening pattern with an exposure apparatus equipped with a high-pressure mercury lamp. The exposure amount was adjusted with a step tablet (Photec 41 stages) so that the gloss sensitivity was 10 stages, and then the polyethylene terephthalate film was peeled off from the photosensitive dry film to expose the photosensitive resin layer. Thereafter, development was performed for 60 seconds with a 1% by mass of Na₂CO₃ aqueous solution at 30° C. under the condition of a spray pressure of 2 kg/cm². The substrate having this cured film was irradiated with ultraviolet rays in a UV conveyor furnace under the condition of an integrated exposure amount of 1000 mJ/cm², and then heated and cured at 170° C. for 60 minutes. The resulting cured product was observed with an optical microscope at a magnification of 500 times, and the number of voids generated between L and S was evaluated. The results are shown in Tables 1 and 2.

### <Evaluation Criteria>

◯: No void was observed.
Δ: 1 to 10 voids were observed.
X: 11 or more voids were observed.
   <<Insulation Reliability (B-HAST Resistance (L/S=10/10 μm))>>

A substrate having a cured film was prepared in the same manner as in the preparation of the substrate for evaluation of resolution except that a comb-shaped pattern of L/S=10/10 μm was formed on the substrate and the entire surface was exposed. Then, HAST was performed under the conditions of 130° C., 85% RH, an applied voltage of 3.5 V, and measurement in the tank. The evaluation criteria are as follows. The results are shown in Tables 1 and 2.

### <Evaluation Criteria>

⊚: No abnormality even after 400 hours
◯: Short circuit occurred in more than 300 hours and 400 hours or less
Δ: Short circuit occurred in more than 200 hours and 300 hours or less
X: Short circuit occurred in 200 hours or less

### <<Crack Resistance>>

A dry film of each of Examples and Comparative Examples was heated and laminated on a substrate for evaluation of FC-BGA, the substrate formed with a pad pitch of 200 μm, using a vacuum laminator (CVP-300, manufactured by Nikko-Materials Co., Ltd.). In contrast, the exposure amount was adjusted with a step tablet (Photec 41 steps) so that the gloss sensitivity was 10 steps, and then direct imaging exposure was performed with an opening size of 80 μm. Thereafter, the polyethylene terephthalate film was peeled off from the photosensitive dry film to expose the photosensitive resin layer, and development was performed for 60 seconds with a 1% by mass Na₂CO₃ aqueous solution at 30° C. under the condition of a spray pressure of 2 kg/cm² to obtain a pattern of a cured film. Further, after irradiation with ultraviolet rays with an integrated exposure amount of 1000 mJ/cm², the film was heated at 170° C. for 1 hour to be cured. Thereafter, a Au plating treatment, solder bump formation, and a Si chip were mounted to obtain an evaluation substrate. The evaluation substrate obtained as described above was placed in a cooling/heating cycle machine in which a temperature cycle was performed between −65° C. and 150° C., and thermal cycle test (TCT) was performed. Then, the surface of the cured film at 500 cycles and 1000 cycles was observed. The determination criteria are as follows. The results are shown in Tables 1 and 2.

### <Evaluation Criteria>

⊚: No abnormality at 1000 cycles
◯: No abnormality at 500 cycles, and crack at 1000 cycles
X: Crack at 500 cycles

### <<Heat Resistance>>

A substrate having a cured film was produced in the same manner as in the production of the substrate for evaluation of resolution except that the entire surface was exposed. The rosin-based flux was applied onto the obtained substrate and the substrate was passed through a reflow furnace set at a maximum temperature of 260° C. previously, and the swelling and peeling of the cured coating film were evaluated. The evaluation criteria are as follows. The results are shown in Tables 1 and 2.

### <Evaluation Criteria>

⊚: No swelling or peeling even after 10 times or more of passing
◯: No swelling or peeling even after 5 times or more and less than 10 times of passing
Δ: No swelling or peeling even after one or more and less than 5 times of passing
X: Swelling and peeling at one time of passing

### <<Coatability>>

The dry film of each Example and each Comparative Example was cut into a size of 5 cm×5 cm, the surface of the dry film was observed at a magnification of 500 times using an optical microscope, and the presence or absence of pinholes and their sizes were observed. The evaluation criteria are as follows.

### <Evaluation Criteria>

⊚: No pinholes.
◯: Pinholes of 10 μm or less.
Δ: Pinholes of more than 10 μm and 20 μm or less.
X: Pinholes of more than 20 μm.

TABLE 1

| | Example | Example | Example | Example | Example | Example | Example | Example | Example |
|---|---|---|---|---|---|---|---|---|---|
| | 1 | 2 | 3 | 4 | 5 | 6 | 7 | 8 | 9 |
| Carboxyl group-containing | 100 | 100 | 100 | 100 | 100 | 100 | 100 | 100 | 100 |
| resin 1 | | | | | | | | | |
| Carboxyl group-containing | | | | | | | | | |
| resin 2 | | | | | | | | | |
| Photopolymerization | 7 | 7 | 7 | 7 | 7 | 7 | 7 | 7 | 7 |
| initiator | | | | | | | | | |
| Epoxy resin | 50 | 50 | 50 | 50 | 50 | 50 | 50 | 50 | 50 |
| Silica particle organic | 61 | 20 | 45 | 80 | 99 | 122 | 180 | 278 | |
| solvent dispersion 1 | | | | | | | | | |
| (particle size 70 nm, degree | | | | | | | | | |
| of association 2.0) | | | | | | | | | |
| Silica particle organic | | | | | | | | | 61 |
| solvent dispersion 2 | | | | | | | | | |
| (particle size 113 nm, | | | | | | | | | |
| degree of association 1.4) | | | | | | | | | |
| Silica particle organic | | | | | | | | | |
| solvent dispersion 3 | | | | | | | | | |
| (particle size 19 nm, degree | | | | | | | | | |
| of association 1.5) | | | | | | | | | |
| Silica particle organic | | | | | | | | | |
| solvent dispersion 4 | | | | | | | | | |
| (particle size 153 nm, | | | | | | | | | |
| degree of association 1.8) | | | | | | | | | |
| Silica particle organic | | | | | | | | | |
| solvent dispersion 5 | | | | | | | | | |
| (particle size 40 nm, degree | | | | | | | | | |
| of association 2.7) | | | | | | | | | |
| Silica particle organic | | | | | | | | | |
| solvent dispersion 6 | | | | | | | | | |
| (particle size 220 nm, | | | | | | | | | |
| degree of association 2.4) | | | | | | | | | |
| Silica particle organic | | | | | | | | | |
| solvent dispersion 7 | | | | | | | | | |
| (particle size 250 nm, | | | | | | | | | |
| degree of association 2.1) | | | | | | | | | |
| Silica 1 | | | | | | | | | |
| Silica 2 | | | | | | | | | |
| Silica 3 | | | | | | | | | |
| Thermosetting catalyst 1 | 4 | 4 | 4 | 4 | 4 | 4 | 4 | 4 | 4 |
| Thermosetting catalyst 2 | 1 | 1 | 1 | 1 | 1 | 1 | 1 | 1 | 1 |
| Acrylate monomer | 14 | 14 | 14 | 14 | 14 | 14 | 14 | 14 | 14 |
| Rubber particle 1 | 7 | 7 | 7 | 7 | 7 | 7 | 7 | 7 | 7 |
| Rubber particle 2 | | | | | | | | | |
| Filler content (% by mass) | 25 | 10 | 20 | 30 | 35 | 40 | 50 | 60 | 25 |
| Rubber particle content | 3 | 3 | 3 | 3 | 3 | 3 | 2 | 2 | 3 |
| (% by mass) | | | | | | | | | |
| Resolution | ⊚ | ⊚ | ⊚ | ⊚ | ◯ | ◯ | Δ | Δ | ⊚ |
| Embeddability in a circuit | ◯ | ◯ | ◯ | ◯ | ◯ | Δ | Δ | Δ | ◯ |
| Insulation reliability | ⊚ | ⊚ | ⊚ | ⊚ | ⊚ | ◯ | ◯ | ◯ | ⊚ |
| Crack resistance | ⊚ | ◯ | ⊚ | ⊚ | ⊚ | ⊚ | ⊚ | ⊚ | ⊚ |
| Heat resistance | ⊚ | ⊚ | ⊚ | ⊚ | ⊚ | ◯ | ◯ | ◯ | ⊚ |
| Coatability | ◯ | ◯ | ◯ | ◯ | ◯ | ◯ | ◯ | ◯ | ◯ |

| | Example | Example | Example | Example | Example | Example | Example |
|---|---|---|---|---|---|---|---|
| | 10 | 11 | 12 | 13 | 14 | 15 | 16 |
| Carboxyl group-containing | 100 | 100 | | 100 | 100 | 100 | 100 |
| resin 1 | | | | | | | |
| Carboxyl group-containing | | | 100 | | | | |
| resin 2 | | | | | | | |
| Photopolymerization | 7 | 7 | 7 | 7 | 7 | 7 | 7 |
| initiator | | | | | | | |
| Epoxy resin | 50 | 50 | 44 | 50 | 50 | 50 | 50 |
| Silica particle organic | | | 59 | 59 | 31 | 55 | 31 |
| solvent dispersion 1 | | | | | | | |
| (particle size 70 nm, degree | | | | | | | |
| of association 2.0) | | | | | | | |
| Silica particle organic | | | | | | | |
| solvent dispersion 2 | | | | | | | |
| (particle size 113 nm, | | | | | | | |
| degree of association 1.4) | | | | | | | |
| Silica particle organic | 61 | | | | | | |
| solvent dispersion 3 | | | | | | | |
| (particle size 19 nm, degree | | | | | | | |
| of association 1.5) | | | | | | | |
| Silica particle organic | | 61 | | | | | |
| solvent dispersion 4 | | | | | | | |
| (particle size 153 nm, | | | | | | | |
| degree of association 1.8) | | | | | | | |
| Silica particle organic | | | | | | | |
| solvent dispersion 5 | | | | | | | |
| (particle size 40 nm, degree | | | | | | | |
| of association 2.7) | | | | | | | |
| Silica particle organic | | | | | | | |
| solvent dispersion 6 | | | | | | | |
| (particle size 220 nm, | | | | | | | |
| degree of association 2.4) | | | | | | | |
| Silica particle organic | | | | | | | |
| solvent dispersion 7 | | | | | | | |
| (particle size 250 nm, | | | | | | | |
| degree of association 2.1) | | | | | | | |
| Silica 1 | | | | | 31 | 6 | |
| Silica 2 | | | | | | | 31 |
| Silica 3 | | | | | | | |
| Thermosetting catalyst 1 | 4 | 4 | 4 | 4 | 4 | 4 | 4 |
| Thermosetting catalyst 2 | 1 | 1 | 1 | 1 | 1 | 1 | 1 |
| Acrylate monomer | 14 | 14 | 13 | 14 | 14 | 14 | 14 |
| Rubber particle 1 | 7 | 7 | 7 | | 7 | 7 | 7 |
| Rubber particle 2 | | | | | | | |
| Filler content (% by mass) | 25 | 25 | 25 | 25 | 25 | 25 | 25 |
| Rubber particle content | 3 | 3 | 3 | 0 | 3 | 3 | 3 |
| (% by mass) | | | | | | | |
| Resolution | ⊚ | ⊚ | ⊚ | ⊚ | ⊚ | ⊚ | ⊚ |
| Embeddability in a circuit | ◯ | ◯ | ◯ | ◯ | ◯ | ◯ | ◯ |
| Insulation reliability | ⊚ | ⊚ | ⊚ | ⊚ | ⊚ | ⊚ | ⊚ |
| Crack resistance | ⊚ | ⊚ | ⊚ | ◯ | ⊚ | ⊚ | ⊚ |
| Heat resistance | ⊚ | ⊚ | ⊚ | ◯ | ⊚ | ⊚ | ⊚ |
| Coatability | ◯ | ◯ | ◯ | ◯ | ⊚ | ⊚ | ⊚ |

TABLE 2

| | Example | Example | Example | Example | Example | Example | Example | Example 1 |
|---|---|---|---|---|---|---|---|---|
| | 17 | 18 | 19 | 20 | 21 | 22 | 23 | Comparative |
| Carboxyl group-containing | 100 | 100 | 100 | 100 | 100 | 100 | 100 | 100 |
| resin 1 | | | | | | | | |
| Carboxyl group-containing | | | | | | | | |
| resin 2 | | | | | | | | |
| Photopolymerization initiator | 7 | 7 | 7 | 7 | 7 | 7 | 7 | 7 |
| Epoxy resin | 50 | 50 | 50 | 50 | 50 | 50 | 50 | 50 |
| Silica particle organic solvent | 31 | 29 | 61 | 58 | 60 | 64 | 68 | |
| dispersion 1 (particle size 70 | | | | | | | | |
| nm, degree of association | | | | | | | | |
| 2.0) | | | | | | | | |
| Silica particle organic solvent | | | | | | | | |
| dispersion 2 (particle size | | | | | | | | |
| 113 nm, degree of | | | | | | | | |
| association 1.4) | | | | | | | | |
| Silica particle organic solvent | | | | | | | | |
| dispersion 3 (particle size 19 | | | | | | | | |
| nm, degree of association | | | | | | | | |
| 1.5) | | | | | | | | |
| Silica particle organic solvent | | | | | | | | |
| dispersion 4 (particle size | | | | | | | | |
| 153 nm, degree of | | | | | | | | |
| association 1.8) | | | | | | | | |
| Silica particle organic solvent | | | | | | | | 61 |
| dispersion 5 (particle size 40 | | | | | | | | |
| nm, degree of association | | | | | | | | |
| 2.7) | | | | | | | | |
| Silica particle organic solvent | | | | | | | | |
| dispersion 6 (particle size | | | | | | | | |
| 220 nm, degree of | | | | | | | | |
| association 2.4) | | | | | | | | |
| Silica particle organic solvent | | | | | | | | |
| dispersion 7 (particle size | | | | | | | | |
| 250 nm, degree of | | | | | | | | |
| association 2.1) | | | | | | | | |
| Silica 1 | | 29 | | | | | | |
| Silica 2 | | | | | | | | |
| Silica 3 | 31 | | | | | | | |
| Thermosetting catalyst 1 | 4 | 4 | 4 | 4 | 4 | 4 | 4 | 4 |
| Thermosetting catalyst 2 | 1 | 1 | 1 | 1 | 1 | 1 | 1 | 1 |
| Acrylate monomer | 14 | 14 | 14 | 14 | 14 | 14 | 14 | 14 |
| Rubber particle 1 | 7 | | | 0.3 | 1.2 | 17 | 27 | 7 |
| Rubber particle 2 | | | 7 | | | | | |
| Filler content (% by mass) | 25 | 25 | 25 | 25 | 25 | 25 | 25 | 25 |
| Rubber particle content | 3 | 0 | 3 | 0.1 | 0.5 | 7 | 10 | 3 |
| (% by mass) | | | | | | | | |
| Resolution | ⊚ | ⊚ | ⊚ | ⊚ | ⊚ | ⊚ | ◯ | ◯ |
| Embeddability in a circuit | ◯ | ◯ | ◯ | ◯ | ◯ | ◯ | ◯ | X |
| Insulation reliability | ⊚ | ⊚ | ⊚ | ⊚ | ⊚ | ⊚ | ◯ | ◯ |
| Crack resistance | ⊚ | ⊚ | ⊚ | ◯ | ⊚ | ⊚ | ⊚ | X |
| Heat resistance | ⊚ | ◯ | ◯ | ◯ | ⊚ | ⊚ | ⊚ | Δ |
| Coatability | ⊚ | ⊚ | ◯ | ◯ | ◯ | ◯ | ◯ | Δ |

| | Example 2 | Example 3 | Example 4 | Example 5 | Example 6 |
|---|---|---|---|---|---|
| | Comparative | Comparative | Comparative | Comparative | Comparative |
| Carboxyl group-containing | 100 | 100 | 100 | 100 | 100 |
| resin 1 | | | | | |
| Carboxyl group-containing | | | | | |
| resin 2 | | | | | |
| Photopolymerization initiator | 7 | 7 | 7 | 7 | 7 |
| Epoxy resin | 50 | 50 | 50 | 50 | 50 |
| Silica particle organic solvent | | | 10 | 340 | |
| dispersion 1 (particle size 70 | | | | | |
| nm, degree of association | | | | | |
| 2.0) | | | | | |
| Silica particle organic solvent | | | | | |
| dispersion 2 (particle size | | | | | |
| 113 nm, degree of | | | | | |
| association 1.4) | | | | | |
| Silica particle organic solvent | | | | | |
| dispersion 3 (particle size 19 | | | | | |
| nm, degree of association | | | | | |
| 1.5) | | | | | |
| Silica particle organic solvent | | | | | |
| dispersion 4 (particle size | | | | | |
| 153 nm, degree of | | | | | |
| association 1.8) | | | | | |
| Silica particle organic solvent | | | | | |
| dispersion 5 (particle size 40 | | | | | |
| nm, degree of association | | | | | |
| 2.7) | | | | | |
| Silica particle organic solvent | 61 | | | | |
| dispersion 6 (particle size | | | | | |
| 220 nm, degree of | | | | | |
| association 2.4) | | | | | |
| Silica particle organic solvent | | 61 | | | |
| dispersion 7 (particle size | | | | | |
| 250 nm, degree of | | | | | |
| association 2.1) | | | | | |
| Silica 1 | | | | | 61 |
| Silica 2 | | | | | |
| Silica 3 | | | | | |
| Thermosetting catalyst 1 | 4 | 4 | 4 | 4 | 4 |
| Thermosetting catalyst 2 | 1 | 1 | 1 | 1 | 1 |
| Acrylate monomer | 14 | 14 | 14 | 14 | 14 |
| Rubber particle 1 | 7 | 7 | 7 | 7 | 7 |
| Rubber particle 2 | | | | | |
| Filler content (% by mass) | 25 | 25 | 5 | 65 | 40 |
| Rubber particle content | 3 | 3 | 3 | 1 | 3 |
| (% by mass) | | | | | |
| Resolution | X | X | ⊚ | X | X |
| Embeddability in a circuit | X | ◯ | ◯ | X | ◯ |
| Insulation reliability | ◯ | ◯ | X | ◯ | ◯ |
| Crack resistance | X | ◯ | X | ◯ | ◯ |
| Heat resistance | Δ | ◯ | X | ◯ | ◯ |
| Coatability | Δ | Δ | Δ | X | Δ |

1: A curable resin composition, comprising:
a carboxyl group-containing resin;
a photopolymerization initiator;
a thermosetting resin; and
silica,
wherein a blending amount of the silica is in a range of 10 to 60% by mass relative to a total solid content of the curable resin composition, and the silica includes nanosilica having an average secondary particle size of 200 nm or less and a degree of association of 2.3 or less.

2: The curable resin composition according to claim 1, wherein the silica further includes a second silica different from the nanosilica such that the second silica has an average secondary particle size of more than 200 nm.

3: The curable resin composition according to claim 2, wherein the second silica has an average secondary particle size in a range of 400 nm to 1600 nm.

4: The curable resin composition according to claim 1, wherein a blending amount of the nanosilica is 50% by mass or more relative to a total blending amount of the silica.

5: The curable resin composition according to claim 1, wherein the curable resin composition further includes rubber particles.

6: A dry film, comprising:
a resin layer obtained by a process comprising applying and drying the curable resin composition of claim 1 on a film.

7: A cured product obtained by a process comprising curing the curable resin composition of claim 1.

8: An electronic component, comprising:
the cured product of claim 7.

9: A cured product obtained by a process comprising curing a resin layer of the dry film of claim 6.

10: An electronic component, comprising:
the cured product of claim 9.

11: The curable resin composition according to claim 2, wherein a blending amount of the nanosilica is 50% by mass or more relative to a total blending amount of the silica.

12: The curable resin composition according to claim 3, wherein a blending amount of the nanosilica is 50% by mass or more relative to a total blending amount of the silica.

13: The curable resin composition according to claim 2, wherein the curable resin composition further includes rubber particles.

14: The curable resin composition according to claim 3, wherein the curable resin composition further includes rubber particles.

15: The curable resin composition according to claim 4, wherein the curable resin composition further includes rubber particles.

16: The curable resin composition according to claim 11, wherein the curable resin composition further includes rubber particles.

17: The curable resin composition according to claim 12, wherein the curable resin composition further includes rubber particles.

18: A dry film, comprising:
a resin layer obtained by a process comprising applying and drying the curable resin composition of claim 2 on a film.

19: A dry film, comprising:
a resin layer obtained by a process comprising applying and drying the curable resin composition of claim 3 on a film.

20: A dry film, comprising:
a resin layer obtained by a process comprising applying and drying the curable resin composition of claim 4 on a film.
